(19) United States
(12) Patent Application Publication
(10) Pub. No.: US 2026/0215131 A1
(43) Pub. Date: Jul. 23, 2026

(54) DISPLAY PANEL

(71) Applicant: Hefei Visionox Technology Co., Ltd., Hefei (CN)

(72) Inventors: Zhiwei ZHOU, Hefei (CN); Jinfang ZHANG, Hefei (CN)

(73) Assignee: Hefei Visionox Technology Co., Ltd., Hefei (CN)

(21) Appl. No.: 19/273,017

(22) Filed: Jul. 17, 2025

(30) Foreign Application Priority Data
Jan. 22, 2025 (CN) 202510115918.9

(51) Int. Cl. H10K 59/80; H10K 59/40; G06F 3/041

(52) U.S. Cl. CPC H10K 59/873; H10K 59/40; G06F 3/0412

(57) ABSTRACT

Embodiments of the present application provide a display panel including: an isolation structure and defining isolation openings; a touch layer disposed on a side of the first sublayer facing away from the substrate and including touch portions, an orthographic projection of each of the touch portions on the substrate being located within an orthographic projection of the first sublayer on the substrate, where a width of the touch portion that has an orthographic projection on the substrate located between two adjacent isolation openings is referred to as a first width, and a width of a portion of the first sublayer located between two adjacent isolation openings is referred to as a second width, the first width of at least part of the touch portions being less than or equal to the second width and greater than or equal to one half of the second width.

### CROSS-REFERENCE TO RELATED APPLICATIONS

The present application claims priority to Chinese Patent Application No. 202510115918.9, filed on January 22, 2025 and entitled " DISPLAY", which is incorporated herein by reference in its entirety.

### FIELD

The present application relates to the field of display, and particularly to a display panel.

### BACKGROUND

During the preparation of conventional display panels, light-emitting pixel patterning is usually implemented by means of a fine metal mask (FMM). FMM technology is mature and has rich experience in mass production. However, FMM technology also has problems such as limited accuracy, high development costs, and long development cycle. Fine metal mask-free technology eliminates the limitations of traditional OLED processes on the size, resolution, and other screen performances of a display screen, and has the advantages of high performance, full-range size, and agile delivery. Reference can be made to relevant contents of the fine metal mask-free technology recited in Chinese patents CN 118251982 A, CN 116648095 A, CN 117062489 A, CN 118742138 A, CN 118678783 A, CN 118660598 A, CN 118675450 A, CN 118824188 A and CN 118781966 A for reference.

### SUMMARY

Embodiments of the present application provide a display panel, with the aim of improving the usage performance of the display panel.

A display panel is provided according to embodiments in one aspect of the present application. The display panel includes: a substrate; an isolation structure disposed on one side of the substrate and defining a plurality of isolation openings in an enclosing manner, the isolation structure including a first sublayer; and a touch layer disposed on a side of the first sublayer facing away from the substrate and including a plurality of touch portions, an orthographic projection of each of the touch portions on the substrate being located within an orthographic projection of the first sublayer on the substrate; where a width of the touch portion that has an orthographic projection on the substrate located between two adjacent isolation openings is referred to as a first width, and a width of a portion of the first sublayer located between two adjacent isolation openings is referred to as a second width, the first width of at least part of the touch portions being less than or equal to the second width and greater than or equal to one half of the second width.

A display panel is provided according to embodiments in another aspect of the present application. The display panel includes: a substrate; an isolation structure disposed on one side of the substrate and defining a plurality of isolation openings in an enclosing manner, the isolation structure including a first sublayer; and a touch layer disposed on a side of the first sublayer facing away from the substrate and including a plurality of touch portions, an orthographic projection of each of the touch portions on the substrate being located within an orthographic projection of the first sublayer on the substrate; where an area of an orthographic projection, on the first sublayer, of the touch portion that has an orthographic projection on the substrate located between two adjacent isolation openings is referred to as a first area, and an area of an orthographic projection, on the substrate, of a portion of the first sublayer corresponding to the touch portion is referred to as a second area, the first area being greater than or equal to one half of the second area and less than or equal to the second area.

A display panel is provided according to embodiments in yet another aspect of the present application. The display panel includes: a substrate; an isolation structure disposed on one side of the substrate and defining a plurality of isolation openings in an enclosing manner, the isolation structure including a first sublayer; and a touch layer disposed on a side of the first sublayer facing away from the substrate and including a plurality of touch portions, an orthographic projection of each of the touch portions on the substrate being located within an orthographic projection of the first sublayer on the substrate; where the touch portion has a thickness greater than or equal to 4,000 angstroms and less than or equal to 6,000 angstroms in a direction perpendicular to a plane where the substrate is located.

The display panel according to an embodiment of the present application includes a substrate, an isolation structure, and a touch layer. The touch layer includes a plurality of touch portions, and an orthographic projection of each touch portion on the substrate is located within an orthographic projection of a first sublayer on the substrate, that is, the touch portion is located above the first sublayer. In this embodiment of the present application, by limiting the first width of at least part of the touch portions to be less than or equal to the second width and greater than or equal to one half of the second width, it is possible to ensure that the first width of the touch portion is not excessively small to reduce the resistance of the touch portion and also prevent the light emission region of the display panel enclosed by the first sublayer from being shielded due to the excessive first width, to ensure the light emission effect of the display panel and avoid a color cast caused by the shielding of the touch portion, thereby improving the usage performance of the display panel.

### BRIEF DESCRIPTION OF THE DRAWINGS

By reading the following detailed description made with reference to the drawings for non-limiting embodiments, the other features, objectives and advantages of the present application will become more apparent, in which the same or similar features are denoted by the same or similar reference numerals.

FIG. 1 is a structural schematic diagram of a display panel according to an embodiment of the present application;

FIG. 2 is a structural schematic partial enlarged view of part A in FIG. 1;

FIG. 3 is a cross-sectional view taken along line B-B in FIG. 2 in an example;

FIG. 4 is a structural schematic partial enlarged view of part C in FIG. 2;

FIG. 5 is a cross-sectional view taken along line B-B in FIG. 2 in another example;

FIG. 6 is a cross-sectional view taken along line D-D in FIG. 2 in an example;

FIG. 7 is a cross-sectional view taken along line B-B in FIG. 2 in yet another example; and

FIG. 8 is a cross-sectional view taken along line B-B in FIG. 2 in yet another example.

### List of reference signs:

1. Substrate;

2. Isolation structure; 21. First sublayer; 22. Second sublayer; 23. Third sublayer;

3. Light-emitting functional layer; 31. Light-emitting structure;

4. Touch layer; 41. Touch portion; 42. insulation layer; 43. Conductive portion;

5. First electrode layer; 6. Second electrode layer;

71. First encapsulation layer; 72. Second encapsulation layer; 73. Third encapsulation layer;

8. Organic layer; 9. Pixel defining layer;

F1. First light-emitting set; F2. Second light-emitting set; K1. Isolation opening; K2. Pixel opening; G. Via; J1. First spacing; J2. Second spacing; X. First direction; Y. Second direction; Z1. First median line; Z2. Second median line.

### DETAILED DESCRIPTION OF THE EMBODIMENTS

The features and exemplary embodiments of the present application in various aspects will be described in detail below. In the following detailed description, many specific details are set forth to comprehensively understand the present application. The following description of the embodiments are merely to provide a better understanding for the present application by illustrating examples of the present application. In the drawings and the following description, at least part of known structures and techniques are not shown to avoid unnecessary ambiguousness of the present application; and for the ease of clarity, the dimensions of part of the structure may be enlarged. In addition, the features, structures or characteristics described below may be combined, in any suitable manner, in one or more embodiments.

In the description of the present application, it should be noted that "a plurality of" means two or more, unless otherwise specified. The orientation or position relationship indicated by the terms "upper", "lower", "left", "right", "inner", "outer", etc. is merely for the convenience of describing the present application and simplifying the description, rather than indicating or implying that a device or element referred to must have a particular orientation or be constructed and operated in a particular orientation, and therefore should not be construed as limiting the present application. Moreover, the terms such as “first” and “second” are merely used for the illustrative purpose, and should not be construed as indicating or implying the relative importance.

The orientation terms used in the following description all indicate directions shown in the accompanying drawings, and do not limit the specific structure of the embodiment of the present application. In the description of the present application, it should also be noted that unless otherwise explicitly specified and defined, the terms “mounting” and “connection” should be understood in a broad sense, for example, they may be a fixed connection, a detachable connection, or an integrated connection, and may be a direct connection, or an indirect connection.

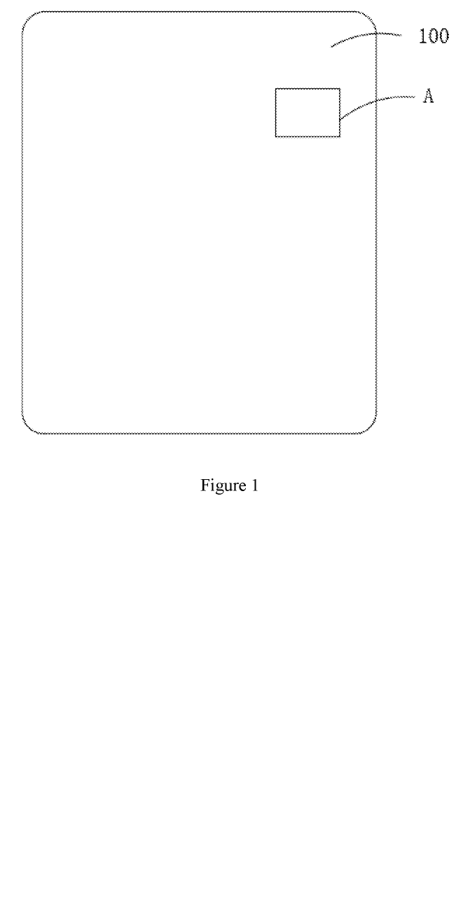

In order to better understand the present application, a display panel according to the embodiments of the present application will be described in detail below with reference to FIGS. 1 to 8.

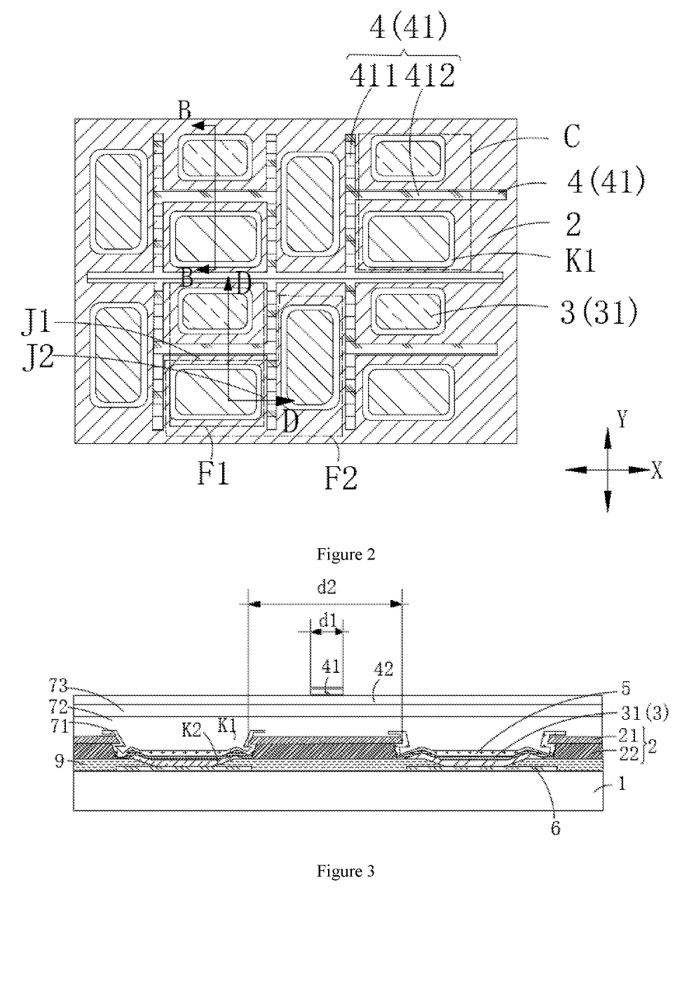

Referring to FIGS. 1 to 3, FIG. 1 is a structural schematic diagram of a display panel according to an embodiment of the present application; FIG. 2 is a structural schematic partial enlarged view of part A in FIG. 1; and FIG. 3 is a cross-sectional view taken along line B-B in FIG. 2 in an example.

The present application provides a display panel 100 including: a substrate 1; an isolation structure 2 disposed on one side of the substrate 1 and defining a plurality of isolation openings K1 in an enclosing manner, the isolation structure 2 including a first sublayer 21; and a touch layer 4 disposed on a side of the first sublayer 21 facing away from the substrate 1, the touch layer 4 including a plurality of touch portions 41, an orthographic projection of each touch portion 41 on the substrate 1 being located within an orthographic projection of the first sublayer 21 on the substrate 1. A width of the touch portion 41 that has an orthographic projection on the substrate 1 located between two adjacent isolation openings K1 is referred to as a first width d1, and a width of a portion of the first sublayer 21 located between two adjacent isolation openings is referred to as a second width d2. The first width d1 of at least part of the touch portions 41 is less than or equal to the second width d2 and greater than or equal to one half of the second width d2. It should be understood that a width direction is a direction perpendicular to an extension direction of the touch portion 41 that has an orthographic projection on the substrate 1 located between two adjacent isolation openings K1.

The display panel 100 according to an embodiment of the present application includes a substrate 1, an isolation structure 2, and a touch layer 4. The touch layer 4 includes touch portions 41, and an orthographic projection of each touch portion 41 on the substrate 1 is located within an orthographic projection of a first sublayer 21 on the substrate 1, that is, the touch portion 41 is located above the first sublayer 21. In this embodiment of the present application, by limiting the first width d1 of at least part of the touch portions 41 to be less than or equal to the second width d2 and greater than or equal to one half of the second width d2, it is possible to ensure that the first width d1 of the touch portion 41 is not excessively small to reduce the resistance of the touch portion 41 and also prevent the light emission region of the display panel 100 enclosed by the first sublayer 21 from being shielded due to the excessive first width d1, to ensure the light emission effect of the display panel 100 and avoid a color cast caused by the shielding of the touch portion 41, thereby improving the usage performance of the display panel 100.

In this embodiment, the touch portions 41 may form a grid-like touch electrode to implement a touch function of the display panel 100. In one embodiment, each touch portion 41 includes a metal material, such as copper, aluminum, molybdenum, and titanium.

It should be noted that the first width d1 and the second width d2 respectively refer to widths of the touch portion 41 and of the first sublayer 21 in one direction, that is, a direction perpendicular to the extension direction of the touch portion 41 that has an orthographic projection on the substrate 1 located between two adjacent isolation openings K1.

It should be understood that, the larger the first width d1 of the touch portion 41, the smaller the resistance of the touch portion 41; and conversely, the smaller the first width d1 of the touch portion 41, the larger the resistance of the touch portion 41. The inventors have found through research that when the first width d1 of the touch portion 41 is less than or equal to the second width d2 and greater than or equal to one half of the second width d2, the touch portion 41 has a small resistance that meets the requirements, and does not block the light emission of the display panel 100.

In one embodiment, the substrate 1 may be a rigid substrate 1, such as a glass substrate 1; or may be a flexible substrate 1 made of polyimide, polystyrene, polyethylene terephthalate, poly-p-xylylene, polyethersulfone or polyethylene naphthalate. The substrate 1 is mainly configured to support devices disposed thereon.

In one embodiment, the display panel 100 further includes a light-emitting functional layer 3. The light-emitting functional layer 3 includes a plurality of light-emitting structures 31 at least partially located in the isolation openings K1.

In one embodiment, each isolation structure 2 is made of a material including a conductive material, a first electrode layer 5 is provided on a side of the light-emitting functional layer 3 facing away from the substrate 1, and the first electrode layer 5 is electrically connected to the isolation structure 2.

In one embodiment, a second electrode layer 6 is provided on a side of the light-emitting functional layer 3 facing the substrate 1.

The material of the first electrode layer 5 may be one of metal materials such as silver (Ag), aluminum (Al), lithium (Li), magnesium (Mg), ytterbium (Yb), calcium (Ca), or indium (In), and may also be an alloy of the foregoing metal materials, such as a magnesium-silver alloy (Mg/Ag), and a lithium-aluminum alloy (Li/Al), which is not limited in this embodiment.

The second electrode layer 6 is generally made of a material having a high work function, which is conducive to improving the hole injection efficiency, and may be gold (Au), platinum (Pt), titanium (Ti), silver (Ag), indium tin oxide (ITO), zinc tin oxide (IZO), or transparent conductive polymers (such as polyaniline), etc. For example, the second electrode layer 6 may be made of an ITO-Ag-ITO composite material, and there is no special limitation thereon.

In one embodiment, the light-emitting structure 31 includes one or more of an electron injection layer, an electron transport layer, a light-emitting material layer, a hole blocking layer, an electron blocking layer, a hole transport layer, and a hole injection layer. This can be specifically selected according to the specific type of the light-emitting layer, and there is no special limitation thereon. The electron injection layer, the electron transport layer and the hole blocking layer may be disposed between the second electrode and the light-emitting material layer. The electron blocking layer, the hole transport layer and the hole injection layer may be disposed between the first electrode and the light-emitting material layer.

In one embodiment, the display panel 100 further includes a pixel defining layer 9. The pixel defining layer 9 is disposed between the substrate 1 and the isolation structure 2. The pixel defining layer 9 encloses a plurality of pixel openings K2, each pixel opening K2 is in communication with the corresponding isolation opening K1, and each light-emitting structure 31 is at least partially located in the corresponding pixel opening K2.

In this embodiment, the light-emitting structures 31 may be disposed in the pixel openings K2 to achieve light emission and display of the display panel 100.

In one embodiment, the plurality of pixel openings K2 are spaced apart from each other, and each pixel opening K2 has a light-emitting structure 31 disposed therein.

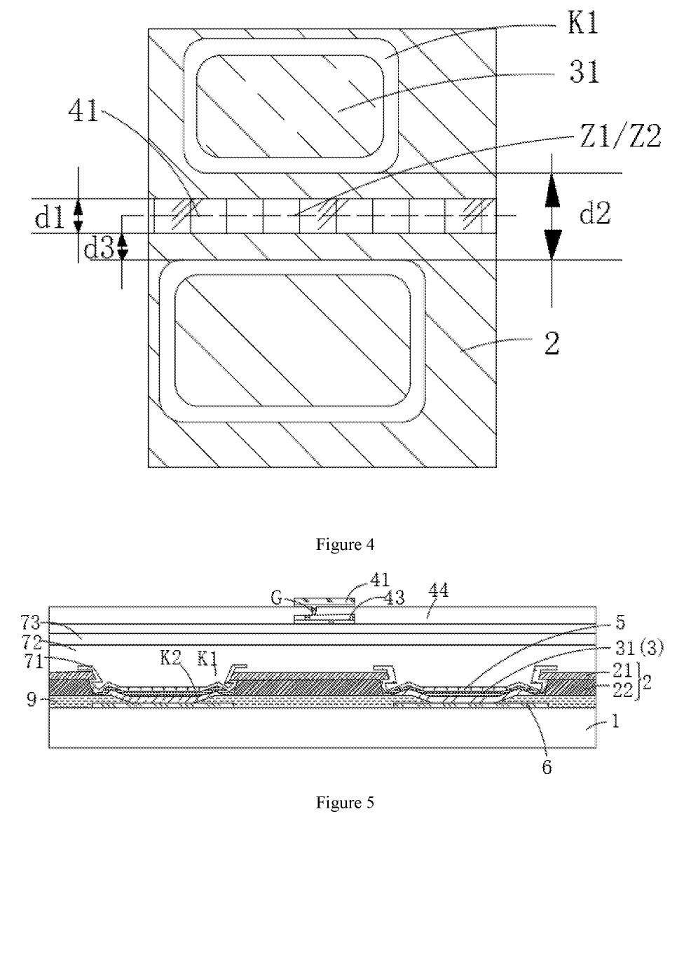

Referring to FIG. 4, in some embodiments, the first width d1 is less than or equal to three quarters of the second width d2 and greater than or equal to one half of the second width d2.

The larger the first width d1 is, the more likely it is to block the light emission of the light-emitting structure 31, causing the light emitted by the light-emitting structure 31 to be refracted at the touch portion 41, resulting in a color cast. Therefore, through research and experiments by the inventors, in this embodiment, the value range of the first width d1 is further limited, and the first width d1 is less than or equal to three quarters of the second width d2, and the shielding area of the touch portion 41 is reduced.

In one embodiment, the first width d1 may be equal to three quarters of the second width d2 or equal to one half of the second width d2.

In one embodiment, the first width d1 is greater than or equal to 3 μm and less than or equal to 10 μm. For example, the first width d1 may be equal to any one of 3 μm, 4 μm, 5 μm, 6 μm, 7 μm, 8 μm, 9 μm, and 10 μm. In one embodiment, the first width d1 is greater than or equal to 3 μm and less than or equal to 6 μm.

In one embodiment, the second width d2 is greater than or equal to 4 μm and less than or equal to 20 μm. For example, the first width d1 may be equal to any one of 4 μm, 6 μm, 8 μm, 10 μm, 12 μm, 14 μm, 16 μm, 18 μm, and 20 μm.

Referring to FIG. 4, in some embodiments, the orthographic projection, on the substrate 1, of the touch portion 41 that has an orthographic projection on the substrate 1 located between two adjacent isolation openings K1 includes a first median line Z1, the orthographic projection, on the substrate 1, of a portion of the first sublayer 21 corresponding to the touch portion 41 includes a second median line Z2, extension directions of the first median line Z1 and of the second median line Z2 are the same as the extension direction of the touch portion 41 that has an orthographic projection on the substrate 1 located between two adjacent isolation openings K1, and the spacing between the first median line Z1 and the second median line Z2 is less than or equal to 2 μm.

It should be understood that since the light-emitting structure 31 is at least partially located in the isolation opening K1, the larger the spacing between the first median line Z1 of the touch portion 41 and the second median line Z2 of the first sublayer 21, the closer the touch portion 41 is to the isolation opening K1, and the more likely it is to affect the light emission of the light-emitting structure 31. In this embodiment, by limiting the spacing between the first median line Z1 and the second median line Z2 in the direction perpendicular to the extension direction of the touch portion 41 to be less than or equal to 2 μm, the touch portion 41 is disposed corresponding to the middle of the first sublayer 21, which prevents the impact on the light emission of the light-emitting structure 31, thereby improving the display effect.

In one embodiment, the spacing between the first median line Z1 and the second median line Z2 may be equal to any one of 0, 1 μm, and 2 μm.

When the spacing between the first median line Z1 and the second median line Z2 is equal to 0, the first median line Z1 coincides with the second median line Z2, and the touch portion 41 is disposed corresponding to the center of the first sublayer 21, which can minimize the impact of the touch portion 41 on the light emission of the light-emitting structure 31.

In order to further reduce the resistance of the touch portion 41, the film thickness of the touch portion 41 may be increased. In some embodiments, a thickness of the touch portion 41 is greater than or equal to 4,000 angstroms and less than or equal to 6,000 angstroms in a direction perpendicular to a plane where the substrate 1 is located. In one embodiment, the thickness of the touch portion 41 is equal to any one of 4,000 angstroms, 5,000 angstroms, and 6,000 angstroms.

In one embodiment, the thickness of the touch portion 41 is greater than or equal to 4,500 angstroms and less than or equal to 6,000 angstroms in the direction perpendicular to the plane where the substrate 1 is located. For example, the thickness of the touch portion 41 is equal to any one of 4,500 angstroms, 5,000 angstroms, and 6,000 angstroms.

Referring to FIG. 4, in some embodiments, a distance d3 between an edge of the orthographic projection, on the substrate 1, of the touch portion 41 that has an orthographic projection on the substrate 1 located between two adjacent isolation openings K1 and an edge of the orthographic projection of the corresponding first sublayer 21 on the substrate 1 is greater than or equal to 3 μm and less than or equal to 10 μm.

It should be understood that the closer the touch portion 41 is to the edge of the first sublayer 21, the closer the touch portion 41 is to the isolation opening K1, and the greater the impact on the light emission of the light-emitting structure 31. Therefore, in this embodiment, by limiting the distance d3 between the edge of the orthographic projection of the touch portion 41 on the substrate 1 and the edge of the orthographic projection of the corresponding first sublayer 21 on the substrate 1 to be greater than or equal to 3 μm and less than or equal to 10 μm, it is possible to prevent the touch portion 41 from being too close to the edge of the first sublayer 21, and also to prevent the distance between the touch portion 41 and the edge of the first sublayer 21 from being excessively large to cause the first width d1 of the touch portion 41 to be excessively small and in turn lead to excessive resistance.

In one embodiment, in the direction perpendicular to the extension direction of the touch portion 41, the distance d3 between the edge of the orthographic projection of the touch portion 41 on the substrate 1 and the edge of the orthographic projection of the corresponding first sublayer 21 on the substrate 1 is equal to 3 μm, 4 μm, 5 μm, 6 μm, 7 μm, 8 μm, 9 μm, or 10 μm.

Referring to FIG. 5, in some embodiments, the display panel 100 further includes a plurality of conductive portions 43 disposed in a different layer from the touch portion 41 and an insulation layer 42 disposed between the touch portion 41 and the conductive portions 43. The conductive portion 43 is connected to the touch portion 41 through a via G disposed in the insulation layer 42.

It should be noted that, in this embodiment, the conductive portion 43 and the touch portion 41 are connected in parallel to reduce the resistance of the touch portion 41. In one embodiment, the touch portion 41 and the conductive portion 43 are made of the same material to reduce the production cost. The insulation layer 42 may be made of an inorganic material such as silicon nitride, silicon oxide, or silicon oxynitride to ensure the insulating properties. It should be understood that, in some embodiments, the conductive portion 43 may be located on a side of the touch portion 41 away from the substrate 1, which is not limited herein.

Referring to FIG. 2, in some embodiments, the touch portion 41 includes a first sub-portion 412 and a second sub-portion 411 connected to each other. The first sub-portion 412 extends in a first direction X, and the second sub-portion 411 extends in a second direction Y. The first direction X and the second direction Y are both parallel to the direction of the plane where the substrate 1 is located, and the first direction X intersects with the second direction Y.

In this embodiment, the first sub-portion 412 and the second sub-portion 411 may extend in the first direction X and the second direction Y, respectively, and be staggered to form a grid-like touch electrode, ensuring the light transmission properties of the display panel 100. In one embodiment, the first direction X is perpendicular to the second direction Y.

In one embodiment, when the first sub-portion 412 extends in the first direction X, the direction perpendicular to the extension direction of the touch portion 41 may refer to the second direction Y. Similarly, when the second sub-portion 411 extends in the second direction Y, the direction perpendicular to the extension direction of the touch portion 41 may refer to the first direction X.

In one embodiment, in the extension directions of the first sub-portion 412 and of the second sub-portion 411, the first sub-portion 412 and the second sub-portion 411 have equal widths to improve the uniformity of arrangement of the touch portion 41, which ensures the uniformity of resistance of the first sub-portion and the second sub-portion while facilitating the preparation.

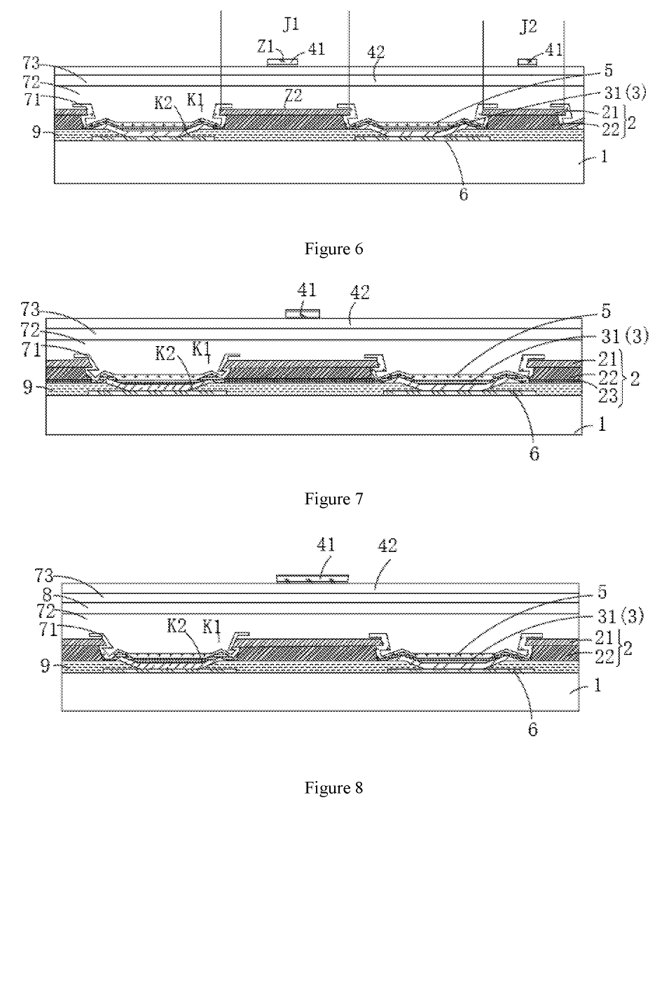

Referring to FIGS. 2 and 6, in some embodiments, the display panel 100 further includes a light-emitting functional layer 3. The light-emitting functional layer 3 includes light-emitting structures 31 at least partially located in the isolation openings K1. The light-emitting functional layer 3 includes at least one first light-emitting set F1 and at least one second light-emitting set F2. The first light-emitting set F1 and the second light-emitting set F2 each include two adjacent light-emitting structures 31. In a direction parallel to the plane where the substrate 1 is located, a first spacing J1 is provided between the orthographic projections, on the substrate 1, of two adjacent light-emitting structures 31 of the first light-emitting set F1, a second spacing J2 is provided between the orthographic projections, on the substrate 1, of two adjacent light-emitting structures 31 of the second light-emitting set F2, and the first spacing J1 is greater than the second spacing J2.

It should be understood that, depending on the arrangement of the light-emitting structures 31, the corresponding spacings between two adjacent light-emitting structures 31 may also be different, and accordingly, the portions of the isolation structure 2 located in the spacings are also different in size. In this embodiment, the width of the first sublayer 21 located in the first spacing J1 is greater than the width of the first sublayer 21 located in the second spacing J2, and the width of the touch portion 41 corresponding to the portion of the first sublayer 21 having a larger width is also relatively larger.

In one embodiment, the width of the touch portion 41 located in the first spacing J1 is greater than the width of the touch portion 41 located in the second spacing J2, and the width of the touch portion 41 and the width of the first sublayer 21 are set correspondingly to ensure the light emission effect of the display panel 100 while meeting the requirement of the resistance of the touch portion 41.

In one embodiment, the light-emitting functional layer 3 includes at least two light-emitting structures 31 emitting light of different colors.

Referring to FIG. 7, in some embodiments, in a direction away from the substrate 1, the isolation structure 2 includes a second sublayer 22 and a first sublayer 21 which are stacked, and an orthographic projection of the second sublayer 22 on the substrate 1 is located within an orthographic projection of the first sublayer 21 on the substrate 1.

The orthographic projection of the second sublayer 22 on the substrate 1 is located within the orthographic projection of the first sublayer 21 on the substrate 1. That is, the dimension of the second sublayer 22 is smaller than or equal to the dimension of the first sublayer 21. In one embodiment, the first sublayer 21 includes a titanium metal material, and the second sublayer 22 includes an aluminum metal material.

Referring to FIG. 7, optionally, the isolation structure 2 further includes a third sublayer 23 located on a side of the second sublayer 22 away from the first sublayer 21. The orthographic projection of the second sublayer 22 on the substrate 1 is located within an orthographic projection of the third sublayer 23 on the substrate 1. The dimension of the second sublayer 22 is smaller than or equal to the dimension of the third sublayer 23.

In some embodiments, the display panel 100 further includes a light-emitting functional layer 3 and a first encapsulation layer 71. The light-emitting functional layer 3 includes light-emitting structures 31 at least partially located in the isolation openings K1, and at least part of the first encapsulation layer 71 is disposed on a side of the light-emitting functional layer 3 facing away from the substrate 1. The first encapsulation layer 71 is configured to provide sealing protection for the light-emitting structures 31.

In one embodiment, the first encapsulation layer 71 includes a first sub-portion disposed on the side of the light-emitting functional layer 3 facing away from the substrate 1 and a second sub-portion connected to a peripheral side of the first sub-portion, part of the second sub-portion is located on a side of the isolation structure 2 facing away from the substrate 1, the first sub-portion is configured to encapsulate and protect the light-emitting structure 31, and the second sub-portion is configured to encapsulate and protect the isolation structure 2.

In one embodiment, the first encapsulation layer 71 includes an inorganic material.

In one embodiment, the display panel 100 further includes a second encapsulation layer 72. The second encapsulation layer 72 is disposed on a side of the first encapsulation layer 71 facing away from the substrate 1, the second encapsulation layer 72 is made of a material including an organic material, and the second encapsulation layer 72 may have an appropriate thickness and a surface of the second encapsulation layer 72 facing away from the substrate 1 is flatter, thereby further improving the flatness of the display panel 100.

In one embodiment, the display panel 100 further includes a third encapsulation layer 73 disposed on a side of the second encapsulation layer 72 facing away from the substrate 1.

In one embodiment, the third encapsulation layer 73 is made of a material including an inorganic material, and the third encapsulation layer 73 has good compactness and can improve the encapsulation effect of the display panel 100.

In one embodiment, the first encapsulation layer 71 and the third encapsulation layer 73 are made of the same material to reduce the production cost.

In some embodiments, a thickness of the second encapsulation layer 72 is greater than or equal to 10 μm and less than or equal to 17 μm in the direction perpendicular to the plane where the substrate 1 is located.

It should be noted that, in this embodiment, by increasing the thickness of the second encapsulation layer 72, it is possible to reduce the capacitance between the touch portion 41 and the isolation structure 2, thereby improving the touch performance. For example, the thickness of the second encapsulation layer 72 may be equal to any one of 10 μm, 11 μm, 12 μm, 13 μm, 14 μm, 15 μm, 16 μm, and 17 μm in the direction perpendicular to the plane where the substrate 1 is located.

Referring to FIG. 8, in some embodiments, the display panel 100 further includes an organic layer 8 disposed between the touch layer 4 and the second encapsulation layer 72. A thickness of the organic layer 8 is greater than or equal to 1.5 μm and less than or equal to 5 μm in the direction perpendicular to the plane where the substrate 1 is located.

It should be noted that, in this embodiment, by providing an additional organic layer 8 between the touch layer 4 and the second encapsulation layer 72, it is possible to increase the distance between the touch portion 41 and the light-emitting structure 31 in the direction perpendicular to the plane of the substrate 1 and in turn reduce the capacitance between the touch portion 41 and the isolation structure 2, thereby improving the touch performance. For example, the thickness of the organic layer 8 may be equal to any one of 1.5 μm, 2 μm, 2.5 μm, 3 μm, 3.5 μm, 4 μm, 4.5 μm, and 5 μm in the direction perpendicular to the plane where the substrate 1 is located.

In one embodiment, the organic layer 8 is made of a material including an optical adhesive.

Referring to FIGS. 1 to 4, in another aspect, the embodiments of the present application further provide a display panel 100 including: a substrate 1; an isolation structure 2 disposed on one side of the substrate 1 and defining a plurality of isolation openings K1 in an enclosing manner, the isolation structure 2 including a first sublayer 21; and a touch layer 4 disposed on a side of the first sublayer 21 facing away from the substrate 1, the touch layer 4 including touch portions 41, an orthographic projection of each touch portion 41 on the substrate 1 being located within an orthographic projection of the first sublayer 21 on the substrate 1. An area of an orthographic projection, on the first sublayer 21, of the touch portion 41 that has an orthographic projection on the substrate 1 located between two adjacent isolation openings K1 is referred to as a first area, and an area of an orthographic projection, on the substrate 1, of a portion of the first sublayer 21 corresponding to the touch portion 41 is referred to as a second area. The first area is greater than or equal to one half of the second area and less than or equal to the second area.

The display panel 100 according to the embodiments of the present application includes a substrate 1, an isolation structure 2, and a touch layer 4. The touch layer 4 includes touch portions 41, and an orthographic projection of each touch portion 41 on the substrate 1 is located within an orthographic projection of a first sublayer 21 on the substrate 1, that is, the touch portion 41 is located above the first sublayer 21. In the embodiments of the present application, by limiting the first area corresponding to the touch portion 41 to be greater than or equal to one half of the second area corresponding to the first sublayer 21 and less than or equal to the second area, it is possible to reduce the resistance of the touch portion 41 and also prevent the light emission region of the display panel 100 enclosed by the first sublayer 21 from being shielded due to the excessive first area, to ensure the light emission effect of the display panel 100 and avoid a color cast caused by the shielding of the touch portion 41, thereby improving the usage performance of the display panel 100.

In one embodiment, the first area may be equal to one half of the second area, or the first area may be equal to the second area, that is, the touch portion 41 and the corresponding first sublayer 21 are equal in size.

Referring to FIGS. 1 to 4, in yet another aspect, the embodiments of the present application provide a display panel 100 including: a substrate 1; an isolation structure 2 disposed on one side of the substrate 1 and defining a plurality of isolation openings K1 in an enclosing manner, the isolation structure 2 including a first sublayer 21; and a touch layer 4 disposed on a side of the first sublayer 21 facing away from the substrate 1, the touch layer 4 including touch portions 41, an orthographic projection of each touch portion 41 on the substrate 1 being located within an orthographic projection of the first sublayer 21 on the substrate 1. A thickness of the touch portion 41 is greater than or equal to 4,000 angstroms and less than or equal to 6,000 angstroms in the direction perpendicular to the plane where the substrate 1 is located.

The display panel 100 according to the embodiments of the present application includes a substrate 1, an isolation structure 2 and a touch layer 4. The touch layer 4 includes touch portions 41, and an orthographic projection of each touch portion 41 on the substrate 1 is located within an orthographic projection of a first sublayer 21 on the substrate 1, that is, the touch portion 41 is located above the first sublayer 21. In the embodiments of the present application, by limiting the thickness of the touch portion 41 to be greater than or equal to 4,000 angstroms and less than or equal to 6,000 angstroms in the direction perpendicular to the plane where the substrate 1 is located, it is possible to further reduce the resistance of the touch portion 41, thereby improving the touch effect.

In one embodiment, the display panel 100 further includes a light-emitting functional layer 3. The light-emitting functional layer 3 includes light-emitting structures 31 located in the isolation openings K1.

In one embodiment, the thickness of the touch portion 41 is equal to any one of 4,000 angstroms, 5,000 angstroms, and 6,000 angstroms.

In one embodiment, the thickness of the touch portion 41 is greater than or equal to 4,500 angstroms and less than or equal to 6,000 angstroms in the direction perpendicular to the plane where the substrate 1 is located. For example, the thickness of the touch portion 41 is equal to any one of 4,500 angstroms, 5,000 angstroms, and 6,000 angstroms.

In some embodiments, the width of the touch portion 41 that has an orthographic projection on the substrate 1 located between two adjacent isolation openings K1 is referred to as a first width d1, and the width of the first sublayer 21 between the two adjacent isolation openings K1 is referred to as a second width d2. The first width d1 of at least part of the touch portions 41 is less than or equal to the second width d2 and greater than or equal to one half of the second width d2, which can ensure that the first width d1 of the touch portion 41 is not excessively small to reduce the resistance of the touch portion 41 and also prevent the light emission region of the display panel 100 enclosed by the first sublayer 21 from being shielded due to the excessive first width d1, to ensure the light emission effect of the display panel 100 and avoid a color cast caused by the shielding of the touch portion 41, thereby improving the usage performance of the display panel 100.

In some embodiments, the first width d1 is less than or equal to three quarters of the second width d2 and greater than or equal to one half of the second width d2.

The larger the first width d1 is, the more likely it is to block the light emission of the light-emitting structure 31, causing the light emitted by the light-emitting structure 31 to be refracted at the touch portion 41, resulting in a color cast. Therefore, through research and experiments by the inventors, in this embodiment, the value range of the first width d1 is further limited, and the first width d1 is less than or equal to three quarters of the second width d2, and the shielding area of the touch portion 41 is reduced.

In one embodiment, the first width d1 may be equal to three quarters of the second width d2 or equal to one half of the second width d2.

In one embodiment, the first width d1 is greater than or equal to 3 μm and less than or equal to 10 μm. For example, the first width d1 may be equal to any one of 3 μm, 4 μm, 5 μm, 6 μm, 7 μm, 8 μm, 9 μm, and 10 μm. In one embodiment, the first width d1 is greater than or equal to 3 μm and less than or equal to 6 μm.

In one embodiment, the second width d2 is greater than or equal to 4 μm and less than or equal to 20 μm. For example, the first width d1 may be equal to any one of 4 μm, 6 μm, 8 μm, 10 μm, 12 μm, 14 μm, 16 μm, 18 μm, and 20 μm.

In some embodiments, the orthographic projection, on the substrate 1, of the touch portion 41 that has on orthographic projection on the substrate 1 located between two adjacent isolation openings K1 includes a first median line Z1, the orthographic projection, on the substrate 1, of a portion of the first sublayer 21 corresponding to the touch portion 41 includes a second median line Z2, the extension directions of the first median line Z1 and the second median line Z2 are the same as the extension direction of the touch portion 41 that has an orthographic projection on the substrate 1 located between two adjacent isolation openings K1, and the spacing between the first median line Z1 and the second median line Z2 is less than or equal to 2 μm.

It should be understood that since the light-emitting structure 31 is at least partially located in the isolation opening K1, the larger the spacing between the first median line Z1 of the touch portion 41 and the second median line Z2 of the first sublayer 21, the closer the touch portion 41 is to the isolation opening K1, and the more likely it is to affect the light emission of the light-emitting structure 31. In this embodiment, by limiting the spacing between the first median line Z1 and the second median line Z2 in the direction perpendicular to the extension direction of the touch portion 41 to be less than or equal to 2 μm, the touch portion 41 is disposed corresponding to the middle of the first sublayer 21, which prevents the impact on the light emission of the light-emitting structure 31, thereby improving the display effect.

In one embodiment, the spacing between the first median line Z1 and the second median line Z2 may be equal to any one of 0, 1 μm, and 2 μm.

When the spacing between the first median line Z1 and the second median line Z2 is equal to 0, the first median line Z1 coincides with the second median line Z2, and the touch portion 41 is disposed corresponding to the center of the first sublayer 21, which can minimize the impact of the touch portion 41 on the light emission of the light-emitting structure 31.

Referring to FIG. 3 or 7, in some embodiments, in a direction away from the substrate 1, the isolation structure 2 includes a second sublayer 22 and a first sublayer 21 which are stacked, and an orthographic projection of the second sublayer 22 on the substrate 1 is located within an orthographic projection of the first sublayer 21 on the substrate 1.

The orthographic projection of the second sublayer 22 on the substrate 1 is located within the orthographic projection of the first sublayer 21 on the substrate 1. That is, the dimension of the second sublayer 22 is smaller than or equal to the dimension of the first sublayer 21. In one embodiment, the first sublayer 21 includes a titanium metal material, and the second sublayer 22 includes an aluminum metal material.

Referring to FIG. 7, optionally, the isolation structure 2 further includes a third sublayer 23 located on a side of the second sublayer 22 away from the first sublayer 21. The orthographic projection of the second sublayer 22 on the substrate 1 is located within an orthographic projection of the third sublayer 23 on the substrate 1. The dimension of the second sublayer 22 is smaller than or equal to the dimension of the third sublayer 23.

In one embodiment, the first encapsulation layer 71 includes a first sub-portion disposed on the side of the light-emitting functional layer 3 facing away from the substrate 1 and a second sub-portion connected to a peripheral side of the first sub-portion, part of the second sub-portion is located on a side of the isolation structure 2 facing away from the substrate 1, the first sub-portion is configured to encapsulate and protect the light-emitting structure 31, and the second sub-portion is configured to encapsulate and protect the isolation structure 2.

In one embodiment, the first encapsulation layer 71 includes an inorganic material.

In one embodiment, the display panel 100 further includes a second encapsulation layer 72. The second encapsulation layer 72 is disposed on a side of the first encapsulation layer 71 facing away from the substrate 1, the second encapsulation layer 72 is made of a material including an organic material, and the second encapsulation layer 72 may have an appropriate thickness and a surface of the second encapsulation layer 72 facing away from the substrate 1 is flatter, thereby further improving the flatness of the display panel 100.

In one embodiment, the display panel 100 further includes a third encapsulation layer 73 disposed on a side of the second encapsulation layer 72 facing away from the substrate 1.

In one embodiment, the third encapsulation layer 73 is made of a material including an inorganic material, and the third encapsulation layer 73 has good compactness and can improve the encapsulation effect of the display panel 100.

In one embodiment, the first encapsulation layer 71 and the third encapsulation layer 73 are made of the same material to reduce the production cost.

Referring to FIG. 2, in some embodiments, the display panel 100 further includes a light-emitting functional layer 3. The light-emitting functional layer 3 includes light-emitting structures 31 at least partially located in the isolation openings K1. The light-emitting functional layer 3 includes at least one first light-emitting set F1 and at least one second light-emitting set F2. The first light-emitting set F1 and the second light-emitting set F2 each include two adjacent light-emitting structures 31. In a direction parallel to the plane where the substrate 1 is located, a first spacing J1 is provided between the orthographic projections, on the substrate 1, of two adjacent light-emitting structures 31 of the first light-emitting set F1, a second spacing J2 is provided between the orthographic projections, on the substrate 1, of two adjacent light-emitting structures 31 of the second light-emitting set F2, and the first spacing J1 is greater than the second spacing J2.

It should be understood that, depending on the arrangement of the light-emitting structures 31, the corresponding spacings between two adjacent light-emitting structures 31 may also be different, and accordingly, the portions of the isolation structure 2 located in the spacings are also different in size. In this embodiment, the width of the first sublayer 21 located in the first spacing J1 is greater than the width of the first sublayer 21 located in the second spacing J2, and the width of the touch portion 41 corresponding to the portion of the first sublayer 21 having a larger width is also relatively larger.

In one embodiment, the width of the touch portion 41 located in the first spacing J1 is greater than the width of the touch portion 41 located in the second spacing J2, and the width of the touch portion 41 and the width of the first sublayer 21 are set correspondingly to ensure the light emission effect of the display panel 100 while meeting the requirement of the resistance of the touch portion 41.

In one embodiment, the light-emitting functional layer 3 includes at least two light-emitting structures 31 emitting light of different colors.

Although the present application is described with reference to the embodiments, various modifications can be made, and equivalents can be provided to substitute for the components thereof without departing from the scope of the present application. In particular, the features mentioned in the embodiments can be combined in any manner, provided that there is no structural conflict. The present application is not limited to the specific embodiments disclosed herein but includes all the solutions that fall within the scope of the claims.

1. A display panel, comprising:
a substrate;
an isolation structure disposed on one side of the substrate and defining a plurality of isolation openings in an enclosing manner, the isolation structure comprising a first sublayer; and
a touch layer disposed on a side of the first sublayer facing away from the substrate and comprising a plurality of touch portions, an orthographic projection of each of the plurality of touch portions on the substrate being located within an orthographic projection of the first sublayer on the substrate;
wherein a width of the touch portion that has an orthographic projection on the substrate located between two adjacent isolation openings is referred to as a first width, and a width of a portion of the first sublayer located between two adjacent isolation openings is referred to as a second width, the first width of at least part of the plurality of touch portions being less than or equal to the second width and greater than or equal to one half of the second width.

2. The display panel according to claim 1, wherein the first width is less than or equal to three quarters of the second width and greater than or equal to one half of the second width.

3. The display panel according to claim 1, wherein the orthographic projection, on the substrate, of the touch portion that has an orthographic projection on the substrate located between two adjacent isolation openings comprises a first median line, and an orthographic projection, on the substrate, of a portion of the first sublayer corresponding to the touch portion comprises a second median line, extension directions of the first median line and the second median line being the same as an extension direction of the touch portion that has an orthographic projection on the substrate located between two adjacent isolation openings, and a spacing between the first median line and the second median line being less than or equal to 2 μm.

4. The display panel according to claim 1, wherein the touch portion has a thickness greater than or equal to 4,000 angstroms and less than or equal to 6,000 angstroms in a direction perpendicular to a plane where the substrate is located.

5. The display panel according to claim 1, wherein a distance between an edge of the orthographic projection, on the substrate, of the touch portion that has an orthographic projection on the substrate located between two adjacent isolation openings and an edge of the orthographic projection of the corresponding portion of the first sublayer on the substrate is greater than or equal to 3 μm and less than or equal to 10 μm.

6. The display panel according to claim 1, further comprising a plurality of conductive portions disposed in a different layer from the touch portion and an insulation layer disposed between the touch portion and the plurality of conductive portions, wherein a conductive portion is connected to the touch portion through a via disposed in the insulation layer.

7. The display panel according to claim 1, wherein the touch portion comprises a first sub-portion and a second sub-portion connected to each other, wherein the first sub-portion extends in a first direction, and the second sub-portion extends in a second direction, the first direction and the second direction being both parallel to a direction of the plane where the substrate is located, and the first direction intersecting with the second direction; and
the first sub-portion and the second sub-portion have equal widths in a direction perpendicular to extension directions of the first sub-portion and of the second sub-portion.

8. The display panel according to claim 1, further comprising a light-emitting functional layer which comprises a plurality of light-emitting structures at least partially located in the plurality of isolation openings, wherein the light-emitting functional layer comprises at least one first light-emitting set and at least one second light-emitting set each comprising two adjacent light-emitting structures; and
in a direction parallel to the plane where the substrate is located, a first spacing is provided between orthographic projections, on the substrate, of two adjacent light-emitting structures of the first light-emitting set, and a second spacing is provided between orthographic projections, on the substrate, of two adjacent light-emitting structures of the second light-emitting set, the first spacing being larger than the second spacing.

9. The display panel according to claim 8, wherein a width of the first sublayer located in the first spacing is greater than a width of the first sublayer located in the second spacing.

10. The display panel according to claim 8, wherein a width of the touch portion located in the first spacing is greater than a width of the touch portion located in the second spacing.

11. The display panel according to claim 1, wherein in a direction away from the substrate, the isolation structure comprises a second sublayer and the first sublayer which are stacked, an orthographic projection of the second sublayer on the substrate being located within the orthographic projection of the first sublayer on the substrate.

12. The display panel according to claim 1, further comprising a light-emitting functional layer and a first encapsulation layer, wherein the light-emitting functional layer comprises a plurality of light-emitting structures at least partially located in the plurality of isolation openings, and at least part of the first encapsulation layer is disposed on a side of the light-emitting functional layer facing away from the substrate.

13. The display panel according to claim 12, wherein the display panel further comprises a second encapsulation layer disposed on a side of the first encapsulation layer and of the isolation structure facing away from the substrate;
the second encapsulation layer comprises an organic material;
the display panel further comprises a third encapsulation layer disposed on a side of the second encapsulation layer facing away from the substrate; and
the third encapsulation layer comprises an inorganic material.

14. The display panel according to claim 13, wherein the second encapsulation layer has a thickness greater than or equal to 10 μm and less than or equal to 17 μm in a direction perpendicular to the plane where the substrate is located.

15. The display panel according to claim 13, further comprising an organic layer disposed between the touch layer and the second encapsulation layer, wherein the organic layer has a thickness greater than or equal to 1.5 μm and less than or equal to 5 μm in a direction perpendicular to the plane where the substrate is located.

16. A display panel, comprising:
a substrate;
an isolation structure disposed on one side of the substrate and defining a plurality of isolation openings in an enclosing manner, the isolation structure comprising a first sublayer; and
a touch layer disposed on a side of the first sublayer facing away from the substrate and comprising a plurality of touch portions, an orthographic projection of each of the plurality of touch portions on the substrate being located within an orthographic projection of the first sublayer on the substrate;
wherein an area of an orthographic projection, on the first sublayer, of the touch portion that has an orthographic projection on the substrate located between two adjacent isolation openings is referred to as a first area, and an area of an orthographic projection, on the substrate, of a portion of the first sublayer corresponding to the touch portion is referred to as a second area, the first area being greater than or equal to one half of the second area and less than or equal to the second area.

17. A display panel, comprising:
a substrate;
an isolation structure disposed on one side of the substrate and defining a plurality of isolation openings in an enclosing manner, the isolation structure comprising a first sublayer; and
a touch layer disposed on a side of the first sublayer facing away from the substrate and comprising a plurality of touch portions, an orthographic projection of each of the plurality of touch portions on the substrate being located within an orthographic projection of the first sublayer on the substrate;
wherein the touch portion has a thickness greater than or equal to 4,000 angstroms and less than or equal to 6,000 angstroms in a direction perpendicular to a plane where the substrate is located.

18. The display panel according to claim 17, wherein a width of the touch portion that has an orthographic projection on the substrate located between two adjacent isolation openings is referred to as a first width, and a width of a portion of the first sublayer located between two adjacent isolation openings is referred to as a second width, the first width of at least part of the touch portions being less than or equal to the second width and greater than or equal to one half of the second width.

19. The display panel according to claim 17, wherein the orthographic projection, on the substrate, of the touch portion located between two adjacent isolation openings comprises a first median line, and an orthographic projection, on the substrate, of a portion of the first sublayer corresponding to the touch portion comprises a second median line, extension directions of the first median line and the second median line being the same as an extension direction of the touch portion that has an orthographic projection on the substrate located between two adjacent isolation openings, and a spacing between the first median line and the second median line being less than or equal to 2 μm; and
the first median line coincides with the second median line.

20. The display panel according to claim 17, further comprising a light-emitting functional layer which comprises a plurality of light-emitting structures at least partially located in the plurality of isolation openings, wherein the light-emitting functional layer comprises at least one first light-emitting set and at least one second light-emitting set each comprising two adjacent light-emitting structures;
in a direction parallel to the plane where the substrate is located, a first spacing is provided between orthographic projections, on the substrate, of two adjacent light-emitting structures of the first light-emitting set, and a second spacing is provided between orthographic projections, on the substrate, of two adjacent light-emitting structures of the second light-emitting set, the first spacing being larger than the second spacing; and
the light-emitting functional layer comprises at least two light-emitting structures emitting light of different colors.
